(19) United States
(12) Patent Application Publication
(10) Pub. No.: US 2014/0278170 A1
(43) Pub. Date: Sep. 18, 2014

(54) STATE OF CHARGE (SOC) DISPLAY FOR RECHARGEABLE BATTERY

(71) Applicant: QUALCOMM Incorporated, San Diego, CA (US)

(72) Inventors: Paolo Baruzzi, Santa Clara, CA (US); Georgios K. Paparrizos, Foster City, CA (US); Giovanni Garcea, San Jose, CA (US)

(73) Assignee: QUALCOMM Incorporated, San Diego, CA (US)

(21) Appl. No.: 14/169,482

(22) Filed: Jan. 31, 2014

Related U.S. Application Data
(60) Provisional application No. 61/798,570, filed on Mar. 15, 2013.

(51) Int. Cl. G01R 31/36

(52) U.S. Cl. CPC G01R 31/3648
USPC 702/63

(57) ABSTRACT

An initial SoC curve may be defined that relates system state of charge (SoC) as a function of battery SoC. Endpoints that define the SoC curve may be updated. For example, each time a battery SoC is determined, the SoC curve may be updated. The SoC curve may then be evaluated to produce a system SoC that can be present to the user.

### CROSS REFERENCE TO RELATED APPLICATIONS

The present disclosure claims priority to U.S. Provisional App. No. 61/798,570 filed Mar. 15, 2013, the content of which is incorporated herein by reference in its entirety for all purposes.

The present disclosure is related to (1) a non-provisional application entitled “ACTIVE MEASUREMENT OF BATTERY EQUIVALENT SERIES RESISTANCE” (Applicant ref. no. 132005U1) filed herewith and (2) U.S. application Ser. No. 13/719,062 entitled “BATTERY FUEL GAUGE” filed Dec. 18, 2012 the content of both of which are incorporated herein by reference in their entireties for all purposes.

### BACKGROUND

Unless otherwise indicated, the foregoing is not admitted to be prior art to the claims recited herein and should not be construed as such.

The amount of electric charge that a battery can store is typically referred to as the battery's “capacity”. The state of charge (SoC) of a battery expresses the battery's present capacity (how much electric charge is presently stored) as a percentage of the battery's maximum capacity (the maximum amount of electric charge that can be stored). The SoC is usually displayed so the user has an idea as to when to recharge the battery. The SoC may not always reflect the battery's actual present capacity, however.

For example, it is typical for some devices to power down when the battery level falls below a cutoff voltage level. The device (e.g., mobile phone) will initiate a power down sequence in order to properly shutdown certain applications and the device itself, for example, in order to maintain data integrity. However, since the battery in fact still contains a non-zero amount of charge, the SoC will accordingly show a non-zero level. This can lead to confusion as the device begins to power down even though the user sees a non-zero SoC.

SoC inaccuracy may arise during battery recharging. The charging sequence for charging a battery includes a so-called “constant current” charging phase where the battery is charged with a constant charging current. When the battery voltage reaches a predetermined voltage level (sometimes referred to as the “charge float voltage”), the charging sequence changes to a so-called “constant voltage” charging phase. In constant voltage charging, a charging current continues to flow into the battery until the current flow falls below a termination current level. Constant voltage charging begins when the battery reaches some percentage (say, for example, 95%) of its capacity, at which time the SoC display will show about 95%. However, the time it takes for battery capacity to reach maximum can be as long as the time it takes for battery capacity to go from 0% to 40%. Accordingly, the user will see the SoC to be at 95% for an unexpectedly long time, which can lead to confusion.

Some battery management systems (BMS) may perform an “auto recharge” sequence when the battery is fully charged. This may happen, for example, if the source of power is still available (e.g., wall adapter is still plugged in). As a result, the displayed SoC may initially display 100% to indicate a fully charged battery, and then display a decreasing SoC as the device consumes power from the battery. Meanwhile, the BMS may perform an auto recharge to bring the battery charge level back up to 100%, and the SoC display will reflect that fact by displaying in increasing SoC. The fluctuations in the displayed SoC resulting from auto recharge can lead to confusion since one would not expect fluctuations to occur when the battery appears fully charged and the adapter is still plugged in.

### SUMMARY

In accordance with the present disclosure, a system state of charge (SoC) is presented to the user in place of a battery SoC that is estimated based on battery measurements. In some embodiments, an SoC curve may be provided to map an estimated battery SoC to a system SoC. The SoC curve may be periodically updated using predetermined voltage and current values, and making battery SoC estimates using the predetermined voltage and current values. The estimated battery SoC may define endpoints of the SoC curve. The SoC curve may then be used to map estimates of battery SoC (made using measurements of battery voltage and battery current) to system SoC, which may then be presented to a user.

The following detailed description and accompanying drawings provide a better understanding of the nature and advantages of the present disclosure.

### BRIEF DESCRIPTION OF THE DRAWINGS

With respect to the discussion to follow and in particular to the drawings, it is stressed that the particulars shown represent examples for purposes of illustrative discussion, and are presented in the cause of providing a description of principles and conceptual aspects of the present disclosure. In this regard, no attempt is made to show implementation details beyond what is needed for a fundamental understanding of the present disclosure. The discussion to follow, in conjunction with the drawings, make apparent to those of skill in the art how embodiments in accordance with the present disclosure may be practiced. In the accompanying drawings:

FIG. 1 illustrates an example of a state of charge (SoC) curve in accordance with the present disclosure.

FIG. 1A shows an illustrative example of an electronic device that may embody the SoC curve.

FIG. 2 illustrates a high level flow of processing using the SoC Curve.

FIG. 3 illustrates how the SoC curve may vary over time.

FIGS. 4 and 4A illustrate an example of how battery SoC can be determined.

FIGS. 5 and 5A illustrate an example of updating an endpoint of the SoC curve.

FIGS. 6 and 6A illustrate another example of updating an endpoint of the SoC curve.

FIG. 7 illustrates an example of a battery model.

### DETAILED DESCRIPTION

In the following description, for purposes of explanation, numerous examples and specific details are set forth in order to provide a thorough understanding of the present disclosure. It will be evident, however, to one skilled in the art that the present disclosure as expressed in the claims may include some or all of the features in these examples, alone or in combination with other features described below, and may further include modifications and equivalents of the features and concepts described herein.

FIG. 1 shows an illustrative example of a state of charge (SoC) curve 100 in accordance with the present disclosure. The SoC curve 100 relates a system SoC as a function of battery SoC. Typically, the SoC curve 100 includes a minimum endpoint 102 that maps a minimum battery SoC value (e.g., min %) to a system SoC value of 0%, and a maximum endpoint 104 that maps a maximum battery SoC value (e.g., max %) to a system SoC value of 100%.

As shown in the embodiment shown in FIG. 1, the SoC curve 100 may be defined using a straight-line segment 100a connected between the minimum and maximum endpoints and two constant-line segments 100b, 100c. It will be appreciated, however, that the SoC curve 100 may be defined using any other suitable non-linear relationships. For purposes of explanation, however, line segments will be used to describe SoC curve 100 without loss of generality. The straight-line segment 100a, for example, may be defined in slope-intercept form:

$$systemSoC = \frac{( batterySoc - {batterySoc}_{min} )}{{batterySoc}_{max} - {batterySoc}_{min}} ,$$

expressed with reference to the terms shown in FIG. 1, where the slope is

$$\frac{1}{{batterySoc}_{max} - {batterySoc}_{min}}$$

$$and the intercept is \\ - \frac{{batterySoc}_{min}}{{batterySoc}_{max} - {batterySoc}_{min}} .$$

In some embodiments, when a computed battery SoC is ≧min % and ≦max %, then the system SoC can be determined in accordance with the expression above. When the computed battery SoC is <min %, the system SoC is 0%, and when the computed battery SoC is >max % the system SoC is 100%. The system SoC may then be presented to the user, e.g., on the display component of an electronic device (e.g., 10, FIG. 1A), to inform the user of a state of charge of the battery that is powering the electronic device.

Referring for a moment to FIG. 1A, the electronic device 10 may include, among other components, device electronics 12, a fuel gauge circuit 14, and a display 16. Battery 22 may be any suitable single or multiple cell device for providing power to the device electronics 12. The fuel gauge 14 may incorporate suitable analog and digital circuitry to support and use the SoC curve 100. A memory 18 may be provided to store data generated by the fuel gauge, to store pre-programmed data, to store data received from a user (e.g., system designer), and so on. The memory 18 may include volatile memory and non-volatile memory (e.g. one-time programmable memory). Although not depicted in the figures, in still other embodiments, the fuel gauge may be incorporated as part of the battery pack and include suitable connectors to provide the display with an SoC output. Still other configurations are possible.

Referring to FIG. 2, the discussion will now turn to a description of processing the SoC curve 100 in accordance with the present disclosure. A general description of the process will be described first. A more specific description of the processing will follow with additional figures and details.

In some embodiments, the processing shown in FIG. 2 may be performed by the fuel gauge 14. For example, the fuel gauge 14 may include a controller such as a data processor or some other digital logic. In other embodiments, various portions of the processing shown in FIG. 2 may be performed by circuitry in addition to or instead of the fuel gauge 14. For discussion purposes, the following explanation will assume, without conceding any generalizations, that processing is performed by the fuel gauge 14.

At block 202, the fuel gauge 14 may receive data that defines an initial SoC curve (e.g., 100). The data may be stored in the memory 18 (FIG. 1A). In some embodiments, the data may be pre-programmed by a system designer into memory 18. In other embodiments, the fuel gauge 14 make an initial estimate of the data. The data may include either or both endpoints 102, 104 (FIG. 1). The fuel gauge 14 may use the received data to generate parameters that describe the SoC curve; e.g., the slope and intercept values of the straight-line segment 100a.

After the SoC curve 100 is initialized, the fuel gauge 14 may compute a value for battery SoC. Thus, for example, at block 204, the fuel gauge 14 may receive a battery voltage measurement. In some embodiments, for example, the fuel gauge 14 may include analog-to-digital converter (ADC) circuitry to make a measurement of the voltage on the battery 22 and perform a conversion to produce a battery voltage measurement. In other embodiments, the battery voltage measurement may be provided by other circuitry in the electronic device 10.

At block 206, the fuel gauge 14 may receive a battery current measurement. In some embodiments, the battery current measurement and the battery voltage measurement may be made concurrently. In some embodiments, the fuel gauge 14 may include an ADC to measure the current flowing through the battery 22 and provide a measurement of the battery current. In other embodiments, the battery current measurement may be provided by other circuitry in the electronic device 10.

At block 208, the fuel gauge 14 may determine or otherwise compute a battery SoC value using the battery voltage and battery current measurements. In some embodiments, for example, the fuel gauge 14 may evaluate a battery model as part of the processing to produce a battery SoC. In some embodiments, the fuel gauge 14 may include circuitry for taking battery temperature to factor in battery temperature in computing the battery SoC. For example, the fuel gauge 14 may include ADC circuitry to make a measurement of the battery temperature. Additional details of the battery SoC will be described below.

At block 210, the fuel gauge 14 may update the SoC curve. In some embodiments, this SoC curve may be updated by updating either or both endpoints (e.g., 102, 104) of the SoC curve. For example, either or both endpoints may be updated by evaluating a battery model. Referring for a moment to FIG. 1, updating either or both endpoints may shift them to the right or left along the Battery SoC axis as illustrated in the figure. When either or both endpoints are updated, the parameters (e.g., slope and intercept values) of the straight-line segment 100a may be recomputed using the updated endpoint value(s). This aspect of the present disclosure will be discussed in more detail below.

At block 212, the fuel gauge 14 may evaluate the SoC curve using the battery SoC determined at block 208 to obtain a system SoC value. The system SoC value may then be presented (block 214) to the user, e.g., on the display component 16 of the electronic device 10.

The process may then return to block 204 and repeated with the next battery voltage and battery current measurements. With each iteration, the SoC curve may be updated. Accordingly, the mapping from battery SoC to system SoC may vary from one iteration to the next. Referring to FIG. 3, for example, the illustration shows an example where both endpoints 302, 304 of a previous SoC curve 300 have been updated 302′, 304′ to define an updated (subsequent) SoC curve 300′. The figure shows that a battery SoC value of X% maps to a system SoC value of Y% on the previous SoC curve 300, while the same battery SoC value maps to a system SoC value of Z% on the updated SoC curve 300′.

Methods for computing battery SoC (block 208, FIG. 2) are known in the art. Applicant's related U.S. application Ser. No. 13/719,062, for example, discloses methods and systems for determining battery SoC. Referring to FIGS. 4 and 4A, the process generally includes evaluating (block 402) a battery model using a measure of the battery current flowing through a battery (e.g., 22, FIG. 1A). The battery model produces a prediction of battery voltage based on the current flowing through the battery and on a present value of the battery SoC. At block 404, the predicted battery voltage is compared with a measure of the battery voltage to produce an error signal. At block 406, the error signal may be integrated (e.g., using an integral controller) to compute a portion of the battery SoC associated with changes in the battery voltage. The measured battery current may be processed by a coulomb counter to compute a portion of the battery SoC associated with the battery current. The two portions may be summed to produce a prediction of the actual battery SoC.

Referring to FIGS. 5 and 5A, an embodiment for updating an endpoint of the SoC curve (e.g., 100) in accordance with the present disclosure will now be described. The figures show, in particular, updating the minimum endpoint (e.g., 102) of the SoC curve. As can be seen in FIG. 5, the process computes a battery SoC value that represents a 0% point of the system SoC. Instead of measured battery current and voltage values, predetermined current and voltage values may be provided to the process (e.g., by a system designer). More particularly, the predetermined current and voltage values that are selected may be associated with some condition that represents a system SoC of 0%. For example, a system cutoff voltage may be used as the predetermined minimum battery voltage level. The system cutoff voltage is typically a voltage level below which the device electronics will no longer operate properly. Accordingly, when the battery voltage falls to the system cutoff voltage, it may be useful to map the corresponding battery SoC value (a non-zero percentage values) to a system SoC value of 0%.

FIG. 5A shows an example of updating the minimum endpoint value using the system cutoff voltage. At block 502, the battery model may be evaluated using an average load current through the battery and a present value of battery SoC. In some embodiments, the average load current, for example, may be obtained by averaging previously measured battery currents. In other embodiments, the average load current may be a preprogrammed value that is stored in memory (e.g., 18). More generally, the current that is used in the battery model may be any suitable value. For example, in some embodiments, the current may be an instantaneous value.

At block 504, the estimated battery voltage produced by the battery model in block 502 may be compared to a predetermined minimum voltage. In a particular embodiment, for example, the minimum voltage level is the system cutoff voltage. As can be seen in FIG. 5A, the comparison produces an error signal that can be integrated to produce (block 506) a value of battery SoC. This value of battery SoC maps to the 0% system SoC value, and thus constitutes the minimum endpoint value of the SoC curve. The processing of FIG. 5A may be repeated (per the loop in FIG. 2) to iteratively correct the 0% system SoC to meet the desired system cutoff voltage. The corrected 0% system SoC can be referred to as the “cutoff” SoC.

Referring to FIGS. 6 and 6A, an embodiment for updating the maximum endpoint (e.g., 104) of the SoC curve will now be described. As can be seen in FIG. 6, the process computes a battery SoC value that represents a 100% point of the system SoC. Instead of measured battery current and voltage values, predetermined current and voltage values may be provided to the process (e.g., by a system designer). More particularly, the predetermined current and voltage values that are selected may be associated with some condition that represents a system SoC of 100%.

A maximum endpoint condition, for example, may be based on battery charging. Battery charging conventionally occurs in two phases, a constant current phase followed by a constant voltage phase. Battery charging usually proceeds initially in the constant current phase. When the battery voltage reaches a predetermined voltage level (referred to as the “battery charge float voltage”), battery charging then enters a constant voltage phase. Charging continues in this phase until current flowing into the battery falls below a predefined termination current, sometimes referred to as the charger termination current.

When the battery voltage reaches the battery charge float voltage during charging, it may be desirable to show a system SoC of 100%, since the battery voltage will remain substantially at the battery charge float voltage until the charger termination current is reached. Accordingly, in a particular embodiment, the maximum endpoint may be computed using the battery charge float voltage and a “system termination current”. The system termination current may be a value higher than the charger termination current. The system termination current may be pre-programmed value stored in memory 18. In some embodiments, the system termination current may be an instantaneous value measured at the time of switching over from constant current phase to constant voltage phase.

FIG. 6A shows an example of updating the maximum endpoint value using the battery float voltage and system termination current. At block 602, the battery model may be evaluated using the system termination current and a present value of battery SoC to produce an estimated battery voltage. At block 604, the estimated battery voltage may be compared to the battery charge float voltage. As can be seen in FIG. 6, the comparison produces an error signal that can be integrated to produce (block 606) a value of battery SoC. This value of battery SoC maps to the 100% system SoC value, and thus constitutes the maximum endpoint value of the SoC curve. The processing of FIG. 6A may be repeated (per the loop in FIG. 2) to iteratively correct the 100% system SoC to meet the desired battery charge float voltage. The corrected 100% system SoC can be referred to as the “full” SoC.

FIG. 7 illustrates an example of the battery models illustrated in FIGS. 4-6. In addition to a battery current value and a present value of battery SoC, the battery model may receive inputs such as a measured battery temperature and battery state. The battery state may indicate whether the battery is in “discharge” mode or “charging” mode. Charging mode refers to a state when the battery is being re-charged, while discharge mode refers to a state when the battery is not being charged and is powering the device electronics. The direction of the current flow (negative, positive) shown in the model will depend on whether the battery is discharging or charging.

The elements of the battery model may be functions of one or more of the inputs to the battery model. The elements of the battery model may include an open circuit voltage (OCV) element, an equivalent series resistance (ESR) component, and a resistance R_{slow} that represents a transient response behavior of the battery. For example, when the battery model is being evaluated to compute the battery SoC, the current that is provided to the battery model may be the measured battery current. The SoC that is provided to the battery model may be the previously computed battery SoC. When the battery model is being evaluated to update the minimum (maximum) endpoint value of the SoC curve (e.g., 100, FIG. 1), the current that is provided to the battery model may be, for example, the average load current (system termination current), and the SoC may be the previously computed minimum (maximum) battery SoC.

It will be appreciated that the 0% and 100% endpoints (e.g., 102, 104, FIG. 1) of the SoC curve are generally not fixed points. Rather, they may depend on the values of the components of the battery model (e.g., FIG. 7). Accordingly, in some embodiments, when using the battery model to update the 0% endpoint, the series resistance Rₛₑᵣᵢₑₛ of the ESR may be dynamically estimated. A compensation may be extrapolated to predict values of Rₛₑᵣᵢₑₛ for different SoCs. In a particular embodiment, for example, a compensation function f_{RSERIES-COMP}(BatterySoC) may be defined as:

$${f}_{RSERIES \text{-} COMP} ( BatterySoC ) = \frac{{R}_{series} ( 0 \% BatterySoC )}{{R}_{series} ( BatterySoC )} ,$$

where 0% BatterySoC is the battery SoC at the 0% endpoint and

BatterySoC is an estimated battery SoC.

The compensation can be used to produce an Rₛₑᵣᵢₑₛ value for the ESR according to:

$${R}_{series} ( SoC\_CutOff ) = {R}_{series} ( BatterySoC ) \times \frac{{f}_{RSERIES \text{-} COMP} ( BatterySoC )}{{f}_{RSERIES \text{-} COMP} ( SoC\_CutOf )} ,$$

where SoC_CutOff is the corrected 0% system SoC described above.

In various embodiments, the transient response resistor R_{slow} in the battery model for updating the 0% endpoint may be evaluated in several ways. For example:
a table lookup may be provided that relates R_{slow} as a function of SoC_CutOff, battery temperature, and battery state,
an extrapolation from a compensated Rₛₑᵣᵢₑₛ value (e.g., per the above), for example:

$${R}_{slow} ( SoC\_CutOff ) = {k}_{COMP} \times {R}_{series} ( SoC\_CutOff ) ,$$

where k_{COMP} may represent an average of

$$\frac{{R}_{slow} ( SoC )}{{R}_{series} ( SoC )} ,$$

R_{slow} may be estimated in a manner similar to Rₛₑᵣᵢₑₛ, namely:

$${f}_{RSLOW \text{-} COMP} ( BatterySoC ) = \frac{{R}_{slow} ( 0 \% BatterySoC )}{{R}_{slow} ( BatterySoC )} and$$

$${R}_{slow} ( SoC\_CutOff ) = {R}_{slow} ( BatterySoC ) \times \frac{{f}_{RSLOW \text{-} COMP} ( BatterySoC )}{{f}_{RSLOW \text{-} COMP} ( SoC\_CutOf )} .$$

Similarly, in some embodiments, when using the battery model to update the 100% endpoint of the SoC curve, the series resistance Rₛₑᵣᵢₑₛ of the ESR may be dynamically estimated. A compensation may be extrapolated to predict values of Rₛₑᵣᵢₑₛ for different SoCs. In a particular embodiment, for example, a compensation function f_{RSERIES-COMP}(BatterySoC) may be defined as:

$${f}_{RSERIES \text{-} COMP} ( BatterySoC ) = \frac{{R}_{series} ( 100 \% BatterySoC )}{{R}_{series} ( BatterySoC )} ,$$

where 100% BatterySoC is the battery SoC at the 100% endpoint and

BatterySoC is an estimated battery SoC.

The compensation can be used to produce an Rₛₑᵣᵢₑₛ value for the ESR according to:

$${R}_{series} ( SoC\_Full ) = {R}_{series} ( BatterySoC ) \times \frac{{f}_{RSERIES \text{-} COMP} ( BatterySoC )}{{f}_{RSERIES \text{-} COMP} ( SoC\_Full )} ,$$

where SoC_Full is the corrected 100% system SoC described above.

In various embodiments, the transient response resistor R_{SLOW} in the battery model for updating the 100% endpoint may be evaluated in several ways. For example:
a table lookup may be provided that relates R_{slow} as a function of SoC_Full, battery temperature, and battery state,
R_{slow} may be estimated in a manner similar to Rₛₑᵣᵢₑₛ, namely:

$${f}_{RSLOW \text{-} COMP} ( BatterySoC ) = \frac{{R}_{slow} ( 100 \% BatterySoC )}{{R}_{slow} ( BatterySoC )} and$$

$${R}_{slow} ( SoC\_Full ) = {R}_{slow} ( BatterySoC ) \times \frac{{f}_{RSLOW \text{-} COMP} ( BatterySoC )}{{f}_{RSLOW \text{-} COMP} ( SoC\_Full )} .$$

As explained above, the 0% and 100% system SoC endpoints of the SoC curve can vary each time the SoC curve is updated. Consequently, the system SoC for a given battery SoC may increase or decrease; e.g., during a charging state or a discharging state. Accordingly, in some embodiments, the system SoC value may be “filtered” to account for varying SoC curves, before it is presented to the user. In some embodiments, for example, when the system is discharging, only decreases in the system SoC are presented to the user; an increase in system SoC can be ignored and the presently displayed SoC remains unchanged. Conversely, when the system is charging the battery and the charging current is greater than the system demand, then only increases in the system SoC are presented to the user.

When a change in the system SoC follows the system status (e.g., decreases during discharging state or increases during charging state), then a slope filtering may be applied to ensure that the a previously applied monotonic filter will not produce a sudden change in the displayed system SoC when the system crosses over between discharging and charging states; e.g., a power adapter is plugged in, or the power adapter is removed.

The above description illustrates various embodiments of the present disclosure along with examples of how aspects of the particular embodiments may be implemented. The above examples should not be deemed to be the only embodiments, and are presented to illustrate the flexibility and advantages of the particular embodiments as defined by the following claims. Based on the above disclosure and the following claims, other arrangements, embodiments, implementations and equivalents may be employed without departing from the scope of the present disclosure as defined by the claims.

We claim the following:

1. A method for presenting state of charge (SoC) of a battery comprising:
i. storing data, including at least a first endpoint value, representative of an SoC curve that relates a system SoC as a function of a battery SoC;
ii. receiving a battery voltage measurement;
iii. receiving a battery current measurement;
iv. determining a battery SoC value using the battery voltage measurement and the battery current measurement;
v. generating an updated SoC curve by computing an updated first endpoint value of the SoC curve using a predetermined battery voltage value and a predetermined battery current value;
vi. evaluating the updated SoC curve using the battery SoC value to produce a corresponding system SoC value;
vii. displaying the system SoC value; and
repeating steps ii through vii.

2. The method of claim 1 wherein the predetermined battery voltage value is a system cutoff voltage and the predetermined battery current value is an average load current.

3. The method of claim 1 wherein the predetermined battery voltage value is a charge float voltage and the predetermined battery current value is a termination current.

4. The method of claim 1 wherein the first endpoint value is a battery SoC value that represents a 0% value of the system SoC.

5. The method of claim 1 wherein the first endpoint value is a battery SoC value that represents a 100% value of the system SoC.

6. The method of claim 1 wherein the data includes a second endpoint value of the SoC curve, wherein the SoC curve is defined by a straight line between the first and second endpoints.

7. The method of claim 6 wherein updating the SoC curve further includes computing an updated second endpoint value of the SoC curve using a second predetermined battery voltage value and a second predetermined battery current value.

8. A circuit comprising:
a memory having stored therein data representative of an SoC curve that relates a system SoC as a function of a battery SoC; and
a controller configured to:
i. receive a battery voltage measurement;
ii. receive a battery current measurement;
iii. determine a battery SoC value using the battery voltage measurement and the battery current measurement;
iv. generate an updated SoC curve by computing an updated first endpoint value of the SoC curve using a predetermined battery voltage value and a predetermined battery current value;
v. evaluate the updated SoC curve using the battery SoC value to produce a corresponding system SoC value;
vi. display the system SoC value; and
repeat steps i through vi.

9. The circuit of claim 8 wherein the predetermined battery voltage value is a system cutoff voltage and the predetermined battery current value is an average load current.

10. The circuit of claim 8 wherein the predetermined battery voltage value is a charge float voltage and the predetermined battery current value is a termination current.

11. The circuit of claim 8 wherein the first endpoint value is a battery SoC value that represents either a 0% value of the system SoC or a 100% value of the system SoC.

12. The circuit of claim 8 wherein the data includes a second endpoint value of the SoC curve, wherein the SoC curve is defined by a straight line between the first and second endpoints.

13. The circuit of claim 12 wherein updating the SoC curve further includes computing an updated second endpoint value of the SoC curve using a second predetermined battery voltage value and a second predetermined battery current value.

14. The circuit of claim 8 further comprising receiving a battery temperature measurement, wherein determining the battery SoC further uses the battery temperature measurement.

15. A circuit comprising:
first means for storing data, including at least a first endpoint value, representative of an SoC curve that relates a system SoC as a function of a battery SoC;
second means for receiving a battery voltage measurement;
third means for receiving a battery current measurement;
fourth means for determining a battery SoC value using the battery voltage measurement and the battery current measurement;
fifth means for generating an updated SoC curve by computing an updated first endpoint value of the SoC curve using a predetermined battery voltage value and a predetermined battery current value;
sixth means for evaluating the updated SoC curve using the battery SoC value to produce a corresponding system SoC value;
seventh means for displaying the system SoC value; and
means for iterating through the second means to the seventh means.

16. The circuit of claim 15 wherein the predetermined battery voltage value is a system cutoff voltage and the predetermined battery current value is an average load current.

17. The circuit of claim 15 wherein the predetermined battery voltage value is a charge float voltage and the predetermined battery current value is a termination current.

18. The circuit of claim 15 wherein the first endpoint value is a battery SoC value that represents a 0% value of the system SoC or a 100% value of the system SoC.

19. The circuit of claim 15 wherein the data includes a second endpoint value of the SoC curve, wherein the first endpoint value is a battery SoC value that represents a 0% value of the system SoC, the second endpoint value is a battery SoC value that represents a 100% value of the system SoC.

20. The circuit of claim 15 further comprising means for receiving a battery temperature measurement, wherein the fourth means for determining a battery SoC value further uses the battery temperature measurement.
